(19) United States
(12) Patent Application Publication
(10) Pub. No.: US 2008/0009123 A1
(43) Pub. Date: Jan. 10, 2008

(54) Method for Bonding Two Free Surfaces, Respectively of First and Second Different Substrates

(75) Inventors: Marek Kostrzewa, Grenoble (FR); Lea Di Cioccio, Saint Ismier (FR); Guillaume Delapierre, Vif (FR)

Correspondence Address: OLIFF & BERRIDGE, PLC, P.O. BOX 320850, ALEXANDRIA, VA, 22320-4850, US

(73) Assignee: Commissariat A Lenergie Atomique, Paris (FR)

(21) Appl. No.: 11/667,919

(22) PCT Filed: Dec. 6, 2005
(86) PCT No.: PCT/FR05/03049

§ 371 Date: May 17, 2007

(30) Foreign Application Priority Data
Dec. 15, 2004 (FR) 04133353

(51) Int. Cl. H01L 21/30

(52) U.S. Cl. 438/455; 257/E21.211

(57) ABSTRACT

A method for bonding two free surfaces, respectively of first and second different substrates, includes a formation step, on the free surface of the first substrate, of a self-assembled mono-molecular layer consisting of a thiol compound of the SH—R—X type, where —R is a carbonaceous chain and —X is a group selected from the group consisting in —H, —OH and —COOH, at least said free surface of the first substrate being formed by a material able to form molecular bonds with the —SH group of the thiol compound. The method also includes preparing the free surface of the second substrate consisting in saturating the free surface of the second substrate with —H groups if —X is a —H group or with —OH groups if —X is selected from the group consisting in —OH and —COOH, and placing the two free surfaces in contact.

### BACKGROUND OF THE INVENTION

The invention relates to a method for bonding two free surfaces, respectively of first and second different substrates.

### State of the Art

In the microelectronics field, we are increasingly faced with a need for densification of the electronic components on substrates, in particular by integrating numerous heterogeneous functions such as optical functions, high-frequency circuits, molecular circuits and bio-electronic circuits. For example, in the optoelectronics field, it is particularly interesting to integrate opto-electronic functions on silicon substrates, i.e. to transfer semi-conducting materials made of indium phosphide (InP) or gallium arsenide (GaAs) onto silicon substrates. This would in fact enable optical interconnections to be made between the different semi-conducting materials. In the same way, there is an increasing interest in using a glass, aluminium nitride (AlN) or alumina (Al₂O₃) substrate as final support for devices requiring a large heat dissipation, such as high electron mobility transistors (HEMT), power components, etc.

However, at present, a universal substrate, equivalent to a silicon substrate and on which different semi-conducting materials could be epitaxied, does not exist. The material forming the substrate does in fact impose its lattice cell parameter on the epitaxied layer and combination of materials presenting too different lattice cell parameters is not possible. In addition, when epitaxy is heterogeneous, the difference between the thermal expansion coefficients of the substrate and of the epitaxied layer make the stack unusable above a certain temperature range.

One of the current solutions therefore consists in fabricating the components on a suitable substrate and in bonding the components on another substrate. Bonding can for example be performed by metallic bonding, bonding by means of an epoxy adhesive or by molecular bonding. Metallic bonding and bonding by means of an epoxy adhesive do however present numerous limits. Thus, they do not enable an optical link between the substrate and the component bonded onto the substrate to be achieved.

Molecular bonding therefore currently represents an interesting way of joining two substrates together. For example, in the Patent U.S. Pat. No. 6,190,778, molecular bonding of two silicon substrates is obtained by coating the surfaces of the two substrates, made smooth and oxidized, with a mono-molecular layer of an organo-silane containing sulphur. The two surfaces are then placed in contact and subjected to thermal treatment at 170° C. so as to create covalent bonds between two sulphur atoms respectively belonging to the mono-molecular layers of the two substrates. Such a molecular bonding method however only works in the case where the surfaces of the two substrates can be oxidized and the two surfaces have to be functionalized with an organo-silane compound.

According to the article “A model for the silicon wafer bonding process” by R. Stengl et al. (Japanese Journal of Applied Physics, Vol 38, N°10, 1989, pages 1735-1741), the surfaces of two silicon wafers, which have been polished, are ultra-clean and made hydrophilic, can adhere to one another at ambient temperature without requiring application of an additional force. Thus, by studying the bonding energy between silicon wafers according to the temperature, R. Stengl et al. developed a molecular bonding model between two silicon wafers. This molecular bonding model is based on the assumption that the initial bonding process between the two wafers takes place via formation of hydrogen bonds between water molecules adsorbed at the oxidized surface of the silicon wafers, and by then heating the assembly so as to form covalent Si—O—Si bonds between the two substrates. Such a model applies to bonding of two identical silicon wafers and also requires the presence of an oxidized layer on each wafer surface.

In the article “Transfer of 3-in GaAs film on silicon substrate by proton implantation process” (Electronics Letters, 1998, Vol 34, pages 408-409), A. Jalaguier et al. propose a hydrophilic molecular bonding between a GaAs substrate and a silicon substrate. The surface of the GaAs substrate is previously covered with a layer of silicon oxide (SiO₂) and undergoes proton implantation whereas the silicon substrate is covered with a layer of silicon oxide (SiO₂). The surfaces of the two substrates are then polished and cleaned before being placed in contact at ambient temperature, and then heated at a temperature comprised between 400° C. and 700° C. Such a bonding method between two different semi-conducting substrates is however not satisfactory in so far as it still requires the presence of a silicon oxide layer at the surface of the GaAs substrate.

### OBJECT OF THE INVENTION

The object of the invention is to provide a method for bonding two free surfaces, respectively of first and second different substrates remedying the shortcomings of the prior art.

More particularly, the object of the invention is to provide a method enabling a good quality bonding to be obtained between two different substrates, while achieving a high-quality optical, thermal and electrical link between the two substrates even when bonding is performed at ambient temperature.

It is a further object of the invention to provide a bonding method that is easy to implement and does not require any significant addition of material at the level of the interface between the two substrates, nor does it require a specific surface polishing step.

According to the invention, these objects are achieved by the enclosed claims.

More particularly, these objects are achieved by the fact that the method comprises at least the following steps:
a formation step, on the free surface of the first substrate, of a self-assembled mono-molecular layer consisting of a thiol compound of the SH—R—X type, where —R is a carbonaceous chain and —X is a group selected among —H, —OH and —COOH, at least said free surface of the first substrate being constituted by a material able to form molecular bonds with the —SH group of the thiol compound,
a step of preparing the free surface of the second substrate consisting in saturating the free surface of the second substrate with —H groups if —X is a —H group or with —OH groups if —X is selected from —OH and —COOH,
a step of placing the two free surfaces in contact.

According to one feature of the invention, —X is the —OH group.

According to another feature of the invention, —R is an alkyl group.

According to a first development of the invention, the first substrate is a semi-conducting substrate able to form molecular bonds with the —SH group of the thiol compound. More particularly, the first substrate is made from gallium arsenide or from indium phosphide.

According to a second development of the invention, the first semi-conducting substrate comprises a superficial layer the free surface whereof forms the free surface of the first substrate. More particularly, the superficial layer is formed by a material selected among gold, copper, gallium arsenide and indium phosphide.

According to a preferred embodiment, the second substrate is formed by a material selected among silicon, glass, quartz and silica glass.

### DESCRIPTION OF PARTICULAR EMBODIMENTS

First and second different substrates, preferably made from semi-conducting materials, are bonded to one another forming on the one hand a self-assembled mono-molecular layer on a free surface of the first substrate and preparing on the other hand the surface of the second substrate designed to be bonded onto the free surface of the first substrate. More particularly, the first substrate is made of gallium arsenide (GaAs) or indium phosphide (InP) whereas the second substrate is made of silicon.

The self-assembled mono-molecular layer, also called SAM (“surface assembled monolayer”), is formed on the free surface of the first substrate. It is constituted by a thiol compound of the SH—R—X type, where —R is a carbonaceous chain and —X is a group selected among —H, —OH and —COOH. The carbonaceous chain —R can be saturated or unsaturated and it can contain cycles and/or hetero atoms such as nitrogen and/or oxygen. The group —X is preferably constituted by the group —OH.

The thiol compound is preferably selected among alkanethiols of the SH—R—H type, thiocarboxylic acids of the SH—R—COOH type and thioalcohols of the SH—R—OH type. R is more particularly an alkyl group of the —(CH₂)ₙ— type, giving the mono-molecular layer good self-organization properties. More particularly, the thiol compound is selected among thioalcohols of the SH—R—OH type.

Formation of a self-assembled mono-molecular layer constituted by a thiol compound on the free surface of a GaAs or InP substrate is known in the prior art, in particular to chemically modify and control the semi-conducting interfaces in optoelectronic, photovoltaic or photocatalytic devices. It has been described more particularly in the article “Preparation of Self-Assembled Monolayers on InP” by Y. Gu et al (Langmuir, Vol 11, N°6, 1995, pages 1849 to 1581), where a self-assembled layer constituted by an alkanethiol comprising between 5 and 18 carbon atoms is formed on an n-doped InP substrate.

Thus for example, a mono-molecular layer made from a thiol compound can be formed on the free surface of an InP substrate by performing the following successive steps:
Dipping the InP substrate in a hydrofluoric acid solution in order to de-oxidize the free surface of the substrate, i.e. so as to remove any superficial layer of native oxide that may be present on said surface,
Rinsing the InP substrate in deionized water,
Dipping the substrate in a thiol-based solution, the temperature of the dipping bath being able to be close to the ambient temperature, around 70° C. or around 140° C.,
Successive rinsings in one or more solvents such as chloroform, acetone and methanol, in deionized water and/or in ultra-pure water.

Formation of such a mono-molecular layer thus enables the free surface of the first substrate to be functionalized in —X groups and more particularly in —OH groups, by establishing molecular bonds between the material forming the free surface of the first substrate and the —SH group of the thiol compound. By immersing the first substrate in a thiol-based solution, the —SH functions of the thiol molecules are in fact fixed by chemisorption on the whole of the free surface of the first substrate, and Van Der Waals interactions are created between the alkyl groups of the thiol molecules adsorbed at the free surface of the first substrate. Moreover, the longer the alkyl chain of the thiol compound, the greater the Van Der Waals interactions. Due to these interactions, the thiol molecules, fixed by the —SH group on the free surface of the first substrate, organize themselves so as to be kept substantially perpendicularly to the free surface of the first substrate. The —OH groups of the thiol molecules therefore form terminal groups of the free surface of the first substrate. The free surface of the first substrate is then said to be functionalized by the —OH groups.

To enable molecular bonding of the second substrate made from silicon onto the free surface functionalized by the —X group of the first substrate made from InP or GaAs, the silicon second substrate undergoes a preparation or surface treatment saturating the free surface of the second substrate with —H groups if —X is a —H group or with —OH groups if —X is selected among —OH and —COOH. Saturation of the free surface of the second substrate, with —H groups or with —OH groups, can be performed by any known type of method.

Thus, for a first substrate made from InP or GaAs, functionalized by the —OH group, the free surface of the second substrate is saturated with —OH groups.

For example, saturation with —OH groups can be obtained by chemically activating the surface of the silicon substrate, by wet method, in particular by forming a hydrophilic silicon oxide layer on the surface of the substrate. The silicon oxide layer can be formed thermally on the free surface of the silicon substrate or it can be formed by a layer of native oxide. The oxide layer is then activated by wet method chemical treatment, for example by dipping the substrate in water so as to form silanol bonds of the Si—OH type on the surface of the substrate. Suitable acid or alkaline solutions can also be used.

Saturation of a silicon substrate with —OH groups can also be achieved or improved according to the state of the initial surface by surface activation by plasma treatment. Thus, a silicon substrate covered with a layer of native or thermal oxide can be placed in a plasma produced by electric discharges in a gas at low pressure. The surfaces treated by plasma then present an improved chemical reactivity with water and other compounds enabling silanol bonds to be formed. Saturation with —OH groups can also be obtained by ultraviolet radiation treatment under ozone.

Placing the free surfaces of the first and second substrates, respectively functionalized and saturated with —OH groups, in contact then enables molecular bonding to be obtained via the —OH groups common to the free surfaces of the two substrates. The thiol compounds of the first substrate in fact enable the surface of the first substrate to be functionalized in —OH groups whereas surface preparation of the second substrate enables silanol bonds to be formed on the free surface of the second substrate. These two steps then enable dangling bonds terminated by —OH groups to be formed on the free surface of the first and second substrates. Then, by placing the two surfaces in contact, the dangling bonds respectively of the first and second substrates combine together and create a molecular bond between the two substrates. Functionalizing the free surface of the first substrate in —X groups, and more particularly in —OH groups, and saturating the free surface of the second substrate with the same —X groups then enables a molecular bonding between two different substrates to be obtained that is of good quality, is easy to implement and doesn't damage the two substrates. In addition, this ensures a high-quality optical, thermal and electrical link between the two substrates even when bonding is performed at ambient temperature. Moreover, it is not necessary to add any material such as a glue at the level of the interface between the two substrates, nor is it necessary to perform a specific polishing step of either or both of the surfaces.

Such a molecular bonding is obtained by means of bonding phenomena which can be compared with the bonding phenomena modeled in the article “A model for the silicon wafer bonding process” by R. Stengl et al, for identical silicon wafers. Bonding between the two different substrates can thus be achieved by formation of hydrogen bonds between water molecules adsorbed at the free surfaces of the first and second substrates. Adsorption of the water molecules on the free surfaces of the substrates is generally obtained by dipping each substrate in water so as to form a water mono-layer at the free surface of each substrate. This bonding step, for a first substrate made of InP and a second substrate made of silicon, can therefore be schematized in the following way: InP—SH—R—OH:(H₂O)₂ . . . (H₂O)₂: OH—Si, the hydrogen bonds being symbolized by the sign “ . . . ” whereas adsorption of the water molecules respectively on the free surface of the InP substrate and on the free surface of the silicon substrate is symbolized par the sign “:”. The adsorbed water then diffuses via the interface between the two surfaces so as to form a covalent —O—Si bond made between the oxygen atom of the first substrate and the silicon of the second substrate. Formation of the covalent —O—Si bond thus enables molecular bonding between the two substrates, such a bonding phenomenon being able to be schematized in the following way: InP—SH—R—O—Si.

Bringing the two free surfaces into contact is preferably performed at ambient temperature. It can also be followed by annealing, called consolidation annealing, performed for example at 200° C. for 24 hours. Such an annealing then strengthens the bonding between the two substrates.

For example, a substrate formed by an InP wafer with a diameter of 50 mm is bonded onto a silicon substrate with a diameter of 100 mm comprising a thermal oxide layer with a thickness of 1 μm.

The surface of the silicon substrate is cleaned and saturated with —OH groups by CARO type treatment (H₂O₂/H₂SO₄) or by any other type of suitable treatment.

The InP wafer is prepared so as to form a mono-molecular layer on the free surface thereof, which layer is formed by the 2-mercaptoethanol compound of semi-structural formula SH—(CH₂)₂—OH. Thus, the InP wafer is de-oxidized in a hydrofluoric acid solution for 5 minutes before being rinsed with water for 10 minutes, and then with isopropanol. It is then immersed for 20 hours in a pure 2-mercaptoethanol solution and rinsed in isopropanol and then in water before being dried.

The surface of the InP wafer thus functionalized is then placed in contact with the surface of the silicon substrate saturated with —OH groups, applying a slight pressure if necessary. Infrared imaging observations have shown that the whole of the InP wafer is bonded to the silicon substrate.

In an alternative embodiment, before the InP wafer is dipped into the thiol solution, the thiol can be de-oxidized in an ultrasonic bath for 5 minutes. This thiol de-oxidizing step enables a possible oxidation of the —SH group to be eliminated, thus enhancing fixing of the thiol on the free surface of the InP wafer. The bonding energies thus obtained between the InP wafer and the silicon substrate are comprised between 100 and 120 mJ/m² at ambient temperature, and between 150 and 250 mJ/m² after consolidation annealing at 200° C. for 24 hours.

The invention is not limited to the embodiments described above. More particularly, the first substrate can be formed by any type of material different from the second substrate, provided that at least the free surface of the first substrate is formed by a material able to form molecular bonds with the —SH group of the thiol compound. For example, the first substrate can comprise a superficial layer the free surface whereof forms the free surface of the first substrate and made from a material able to form molecular bonds with the —SH group of the thiol compound. The superficial layer is for example formed by a material selected among gold, copper, gallium arsenide and indium phosphide. This superficial layer can also be deposited or epitaxied on the first substrate.

Furthermore, in the case of a thioalcohol compound, the silicon substrate can be replaced by a silicon substrate previously comprising a silicon oxide layer or by any type of substrate on which an oxide layer enabling saturation of the free surface with —OH groups is liable to be formed, such as silica glass, quartz or glass (for example made from borophosphosilicate).

1-13. (canceled)

14. Method for bonding two free surfaces, respectively of first and second different substrates, comprising at least the following steps:
a formation step, on the free surface of the first substrate, of a self-assembled mono-molecular layer consisting of a thiol compound of the SH—R—X type, where —R is a carbonaceous chain and —X is a group selected from the group consisting in —H, —OH and —COOH, at least said free surface of the first substrate being constituted by a material able to form molecular bonds with the —SH group of the thiol compound,
a step of preparing the free surface of the second substrate consisting in saturating the free surface of the second substrate with —H groups if —X is a —H group or with —OH groups if —X is selected from —OH and —COOH,
a step of placing the two free surfaces in contact.

15. Method according to claim 14, wherein —X is the —OH group.

16. Method according to claim 14, wherein —R is an alkyl group.

17. Method according to claim 14, wherein the first substrate is a semi-conducting substrate able to form molecular bonds with the —SH group of the thiol compound.

18. Method according to claim 17, wherein the first substrate is made of gallium arsenide or indium phosphide.

19. Method according to claim 14, wherein the first substrate comprises a superficial layer the free surface whereof forms the free surface of the first substrate.

20. Method according to claim 19, wherein the superficial layer is constituted by a material selected from the group consisting in gold, copper, gallium arsenide and indium phosphide.

21. Method according to claim 14, wherein the second substrate is constituted by a material selected from the group consisting in silicon, glass, quartz and silica glass.

22. Method according to claim 15, wherein the saturation step of the free surface of the second substrate with —OH groups is performed by wet method chemical activation.

23. Method according to claim 15, wherein the saturation step of the free surface of the second substrate with —OH groups is performed by plasma treatment.

24. Method according to claim 15, wherein the saturation step of the free surface of the second substrate with —OH groups is performed by ultraviolet radiation treatment under ozone.

25. Method according to claim 14, wherein placing of the two surfaces in contact is performed at a temperature close to the ambient temperature.

26. Method according to claim 14, wherein the step of placing the two surfaces in contact is followed by an annealing step.
